(19) United States
(12) Patent Application Publication
(10) Pub. No.: US 2014/0175508 A1
(43) Pub. Date: Jun. 26, 2014

(54) SEMICONDUCTOR DEVICE WITH SCHOTTKY BARRIER DIODE

(71) Applicants: TOYOTA JIDOSHA KABUSHIKI KAISHA, Toyota-shi (JP); DENSO CORPORATION, Kariya-city (JP)

(72) Inventors: Naohiro SUZUKI, Anjo-city (JP); Akitaka SOENO, Toyota-city (JP); Sachiko AOI, Nagoya-city (JP); Yukihiko WATANABE, Nagoya-city (JP)

(73) Assignees: TOYOTA JIDOSHA KABUSHIKI KAISHA, Toyota-shi (JP); DENSO CORPORATION, Kariya-city (JP)

(21) Appl. No.: 14/138,456

(22) Filed: Dec. 23, 2013

(30) Foreign Application Priority Data
Dec. 26, 2012 (JP) 2012-282290

(51) Int. Cl. H01L 29/872; H01L 29/739

(52) U.S. Cl. CPC H01L 29/872; H01L 29/7393
USPC 257/140

(57) ABSTRACT

A semiconductor device includes a first conductivity-type drift region including an exposed portion, a plurality of second conductivity-type body regions, a first conductivity-type source region, a gate portion and a Schottky electrode. The drift region is defined in a semiconductor layer, and the exposed portion exposes on a surface of the semiconductor layer. The body regions are disposed on opposite sides of the exposed portion. The source region is separated from the drift region by the body region. The gate portion is disposed to oppose the body region. The exposed portion is formed with a groove, and the Schottky electrode is disposed in the groove. The Schottky electrode has a Schottky contact with the exposed portion.

### CROSS REFERENCE TO RELATED APPLICATION

This application is based on Japanese Patent Application No. 2012-282290 filed on Dec. 26, 2012, the disclosure of which is incorporated herein by reference.

### TECHNICAL FIELD

The present disclosure relates to a semiconductor device having a Schottky barrier diode (SBD).

### BACKGROUND

A semiconductor device in which a Schottky barrier diode is integrated in a field-effect transistor has been proposed. JP-A-2006-524432, which corresponds to U.S. Pat. No. 6,979,863 B2, discloses an example of such a semiconductor device.

In JP-A-2006-524432, the Schottky barrier diode is provided between adjacent metal oxide semiconductor (MOS) structures so as to reduce an area consumption. In particular, a portion of an n-type drift region exposes from a surface of a semiconductor layer, and a Schottky electrode is formed to have a Schottky contact with the exposed portion. A forward current of the Schottky barrier diode flows through the exposed portion of the drift region.

### SUMMARY

In such a semiconductor device, in order to increase a current density, an area of the MOS structures per unit area needs to be increased by reducing a distance between the adjacent MOS structures. However, when the distance between the adjacent MOS structures is reduced, the exposed portion of the drift region is depleted by a depletion layer expanding from the body region. As a result, a current path of the Schottky barrier diode is narrowed, and a forward voltage of the Schottky barrier diode is increased.

It is an object of the present disclosure to provide a semiconductor device having a Schottky barrier diode, which is capable of reducing the increase of the forward voltage of the Schottky barrier diode.

According to an aspect of the present disclosure, a semiconductor device includes a first conductivity-type drift region including an exposed portion, second conductivity-type body regions, a first conductivity-type source region, a gate portion, and a Schottky electrode. The drift region is provided in a semiconductor layer. The exposed portion exposes from a surface of the semiconductor layer. The second conductivity-type body regions are disposed on opposite sides of the exposed portion of the first conductivity-type drift region. The first conductivity-type source region is separated from the drift region by the second conductivity-type body region. The gate portion is opposed to the second conductivity-type body region, which separate the source region from the drift region. The Schottky electrode contacts the exposed portion of the first conductivity-type drift region to have a Schottky contact with the exposed portion. The exposed portion is formed with a groove. The Schottky electrode is disposed in the groove.

In the above semiconductor device, since the Schottky electrode is disposed in the groove of the exposed portion, an influence of a depletion layer expanding in the exposed portion of the drift region is reduced. Therefore, the increase in forward voltage of the Schottky barrier diode can be restricted.

### BRIEF DESCRIPTION OF THE DRAWINGS

The above and other objects, features and advantages of the present disclosure will become more apparent from the following detailed description made with reference to the accompanying drawings, in which like parts are designated by like reference numbers and in which:

FIG. 1 is a schematic diagram illustrating a perspective view of a part of a semiconductor device, from which a part of a source electrode is removed, according to an embodiment of the present disclosure;

FIG. 2 is a diagram illustrating a cross-sectional view taken along a line II-II in FIG. 1;

FIG. 3 is a diagram illustrating an enlarged cross-sectional view of an exposed portion of a drift region according to the embodiment;

FIG. 4 is a diagram illustrating a cross-sectional view of a part of a semiconductor device according to a modification of the embodiment;

FIG. 5 is a diagram illustrating a perspective view of a part of a semiconductor device, from which a part of a source electrode is removed, according to another embodiment of the present disclosure;

FIG. 6 is a diagram illustrating a perspective view of a part of a semiconductor device, from which a part of a source electrode is removed, according to another embodiment of the present disclosure;

FIG. 7 is a diagram illustrating a perspective view of a part of a semiconductor device, from which a part of a source electrode is removed, according to another embodiment of the present disclosure;

FIG. 8 is a diagram illustrating a perspective view of a part of a semiconductor device, from which a part of a source electrode is removed, according to another embodiment of the present disclosure;

FIG. 9 is a diagram illustrating a perspective view of a part of a semiconductor device, from which a part of a source electrode is removed, according to another embodiment of the present disclosure; and

FIG. 10 is a diagram illustrating a perspective view of a part of a semiconductor device, from which a part of a source electrode is removed, according to another embodiment of the present disclosure.

### DETAILED DESCRIPTION

Hereinafter, embodiments of the present disclosure will be described. The items described hereinafter each have technical usability.

According to an embodiment of the present disclosure, a semiconductor device includes a first conductivity-type drift region, second conductivity-type body regions, a first conductivity-type source region, a gate portion, and a Schottky electrode. The first conductivity-type drift region is defined in a semiconductor layer, and has an exposed portion exposing on a surface of a semiconductor layer. The second conductivity-type body regions are disposed on opposite sides of the exposed portion of the first conductivity-type drift region. The first conductivity-type source region is separated from the drift region by the second conductivity-type body region. The gate portion is opposed to the second conductivity-type body region, which separates the source region from the drift region. The Schottky electrode contacts the exposed portion of the first conductivity-type drift region to have a Schottky contact with the exposed portion. The exposed portion is formed with a groove. The Schottky electrode is disposed in the groove.

Examples of the semiconductor device may be a metal oxide semiconductor field effect transistor (MOSFET) and an insulated gate bipolar transistor (IGBT).

In the semiconductor device, the Schottky electrode has the Schottky contact with the exposed portion of the drift region. Therefore, a Schottky barrier diode is integrated in the exposed portion of the drift region.

The structure of the gate portion may not be limited to a specific one. For example, the gate portion may be a trench gate or a planar gate.

In the semiconductor device, the groove is formed in the exposed portion of the drift region, and the Schottky electrode is disposed in the groove.

The body region may include a contact region between the exposed portion of the drift region and the source region. The contact region has an impurity concentration higher than that of a remaining portion of the body region.

The Schottky electrode disposed in the groove may extend to a position deeper than the contact region. In this case, since the Schottky electrode disposed in the groove extends to a position deeper than a depletion layer that expands in the exposed portion of the drift region from the contact region, an influence of the depletion layer is restricted, and an increase in forward voltage of the Schottky barrier diode can be reduced.

The gate portion may extend in a first direction, when the semiconductor layer is viewed along a direction generally normal to a surface of the semiconductor layer, that is, in a direction normal to a plane surface of the semiconductor layer. The first direction is a direction included in the plane of the semiconductor layer. In this case, the exposed portion of the drift region has a width in a second direction that is perpendicular to the first direction and included in the plane of the semiconductor layer. Also, the contact region of the body region has a width in the second direction. The ratio of the width of the exposed portion and the width of the contact region may vary in the first direction.

The exposed portion of the drift region may have wide portions and narrow portions narrower than the wide portions, in the first direction. In other words, the contact region of the body region may have narrow portions and wide portions wider than the narrow portions, in the first direction. In this case, since the wide portions of the exposed portion or the narrow portions of the contact region exist, the increase in the forward voltage of the Schottky barrier diode is restricted. Also, since the narrow portions of the drift region or the wide portions of the contact region exist, it is less likely that a latch-up will occur.

The Schottky electrode disposed in the groove may extend to a position not deeper than the body region. In this case, an electric field concentration at a bottom surface of the Schottky electrode is alleviated, and a capacity improves.

The semiconductor layer may be a silicon carbide layer.

Hereinafter, exemplary embodiments of the present disclosure will be described more in detail with reference to the drawings.

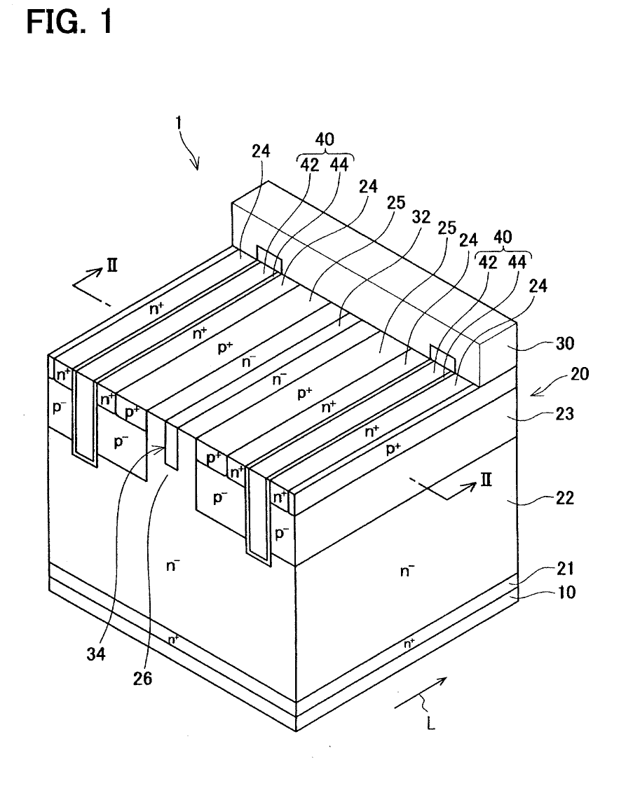

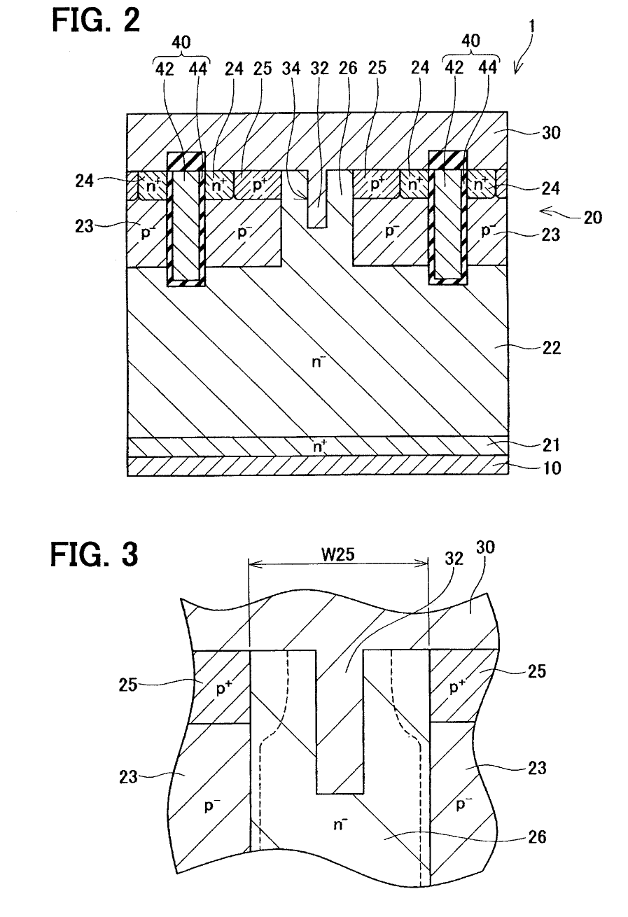

A semiconductor device 1 according to an embodiment will be described with reference to FIG. 1 to FIG. 3. The semiconductor device 1 is a metal oxide semiconductor field effect transistor (MOSFET) integrating a Schottky barrier diode therein. The semiconductor device 1 is, for example, used to an inverter that supplies alternating-current (AC) power to an AC motor. The Schottky barrier diode serves as a freewheel diode. As shown in FIGS. 1 and 2, the semiconductor device 1 includes a drain electrode 10, a silicon carbide layer 20, a source electrode 30, and a trench gate 40.

The drain electrode 10 is formed to cover a rear surface (e.g., lower surface in FIG. 1) of the silicon carbide layer 20. The drain electrode 10 contacts the rear surface of the silicon carbide layer 20 and forms an ohmic contact with the silicon carbide layer 20. As a material of the drain electrode 10, for example, nickel (Ni), titanium (Ti), molybdenum (Mo), or cobalt (Co) may be used.

The silicon carbide layer 20 includes an n-type substrate 21, an n-type drift region 22, p-type body regions 23, and n-type source regions 24. The n-type substrate 21 is a silicon carbide substrate having a surface in a plane direction [0001]. The n-type substrate 21 is also referred to as a drain region. A rear surface (e.g., lower surface in FIG. 1) of the substrate 21 contacts the drain electrode 10 and forms an ohmic contact with the drain electrode 10.

The drift region 22 is disposed on the substrate 21. The drift region 22 has an exposed portion 26 on its top. The exposed portion 26 is formed as a projection. A top surface of the exposed portion 26 exposes on a part of the surface of the silicon carbide layer 20. In other words, the top surface of the exposed portion 26 forms a part of the surface of the silicon carbide layer 20. The exposed portion 26 extends parallel to a longitudinal direction (e.g., arrow L in FIG. 1) of the trench gate 40 arranged in a stripe shape. The longitudinal direction L corresponds to a first direction that is defined in a plane of the silicon carbide layer 20. The drift region 22 is formed by a crystal growth from the substrate 21 using an epitaxial growth technique.

The exposed portion 26 of the drift region 22 is interposed between the body regions 23. That is, the body regions 23 are disposed on opposite sides of the exposed portion 26 of the drift region 22. The body region 23 has a contact region 25 on its top. The contact region 25 is disposed between the exposed portion 26 of the drift region 22 and the source region 24. The contact region 25 exposes at a part of the surface of the silicon carbide layer 20. The contact region 25 has a relatively high impurity concentration.

The contact region 25 has a function of restricting a latch-up. The contact region 25 restricts a part of holes toward the source electrode 30 from flowing into the source region 24, when the Schottky barrier diode carries out a recovery operation. Therefore, the contact region 25 is disposed adjacent to the source region 24 and has a certain amount of area. The contact region 25 extends in the longitudinal direction L. The body region 23 is formed by introducing a p-type impurity from the surface of the silicon carbide layer 20. The p-type impurity is introduced two or more times by an ion implantation technique while changing a range distance. For example, the p-type impurity is aluminum.

The source region 24 is disposed on the body region 23, and is separated from the drift region 22 by the body region 23. Also, the source region 24 exposes at a part of the surface of the silicon carbide layer 20. The source region 24 extends parallel to the longitudinal direction L. The source region 24 is formed by introducing an n-type impurity from the surface of the silicon carbide layer 20 by an ion implantation technique. For example, the n-type impurity is phosphorous (P).

The source electrode 30 covers the surface of the silicon carbide layer 20. The source electrode 30 contacts the source region 24, the contact region 25 of the body region 23, and the exposed portion 26 of the drift region 22, which expose on the surface of the silicon carbide layer 20.

The exposed portion 26 of the drift region 22 is formed with a groove 34. A part of the source electrode 30 is disposed in the groove 34. Hereinafter, the part of the source electrode 30 disposed in the groove 34 is referred to as a trench Schottky electrode 32.

The trench Schottky electrode 32 extends parallel to the longitudinal direction L. The source electrode 30 forms an ohmic contact with the source region 24 and the contact region 25 of the body region 23. The source electrode 30 forms a Schottky contact with the exposed portion 26 of the drift region 22. As a material of the source electrode 30, for example, Ni, Ti, or Mo may be used. As another example, the source electrode 30 may be formed in such a manner that the portion forming the ohmic contact with the source region 24 and the contact region 25 and the portion forming the Schottky contact with the exposed portion 26 are made of different materials.

The trench gate 40 is opposed to the body region 23, which separates the source region 24 from the drift region 22. The trench gate 40 includes a trench gate electrode 42 and a gate insulation film 44. The trench gate electrode 42 and the gate insulation film 44 are disposed in a trench that extends through the body region 23 from the surface of the silicon carbide layer 20. The gate insulation film 44 covers an inner surface of the trench. The gate insulation film 44 is formed by a chemical vapor deposition (CVD) technique. The trench gate electrode 42 is filled on the gate insulation film 44 in the trench by a chemical vapor deposition (CVD) technique.

FIG. 3 illustrates an enlarged cross-sectional view of a part of the exposed portion 26 of the drift region 22. To increase a current density of the semiconductor device 1, for example, an area of the MOS structure per unit area need to be increased by reducing a distance between adjacent MOS structures. In such a high density semiconductor device 1, however, a distance W25 between the contact regions 25 of the adjacent body regions 23 is short.

For example, in a semiconductor device without having the trench Schottky electrode 32, a conduction path of the exposed portion 26 is narrowed due to a depletion layer expanding from the contact regions 25, as shown by a dashed line in FIG. 3. As a result, a forward voltage of the Schottky barrier diode increases.

In the semiconductor device 1 having the trench Schottky electrode 32, on the other hand, the influence by the narrowing of the conduction path due to the depletion layer can be reduced. Therefore, the increase of the forward voltage of the Schottky barrier diode can be restricted.

As described above, the forming of the trench Schottky electrode 32 is useful in the high density semiconductor device 1.

As shown in FIG. 3, the depletion layer widely expands on the sides of the contact regions 25, which are located at a surface layer portion and have the high impurity concentration. Therefore, the trench Schottky electrode 32 extends to a position deeper than the contact regions 25. In this case, the influence by the narrowing of the conduction path due to the depletion layer can be suitably restricted.

The trench Schottky electrode 32 is disposed at a position shallower than the body regions 23. For example, the trench Schottky electrode 32 ends at a position higher than a bottom end of the body region 23. In this case, an electric field applied to the bottom surface of the trench Schottky electrode 32 can be alleviated.

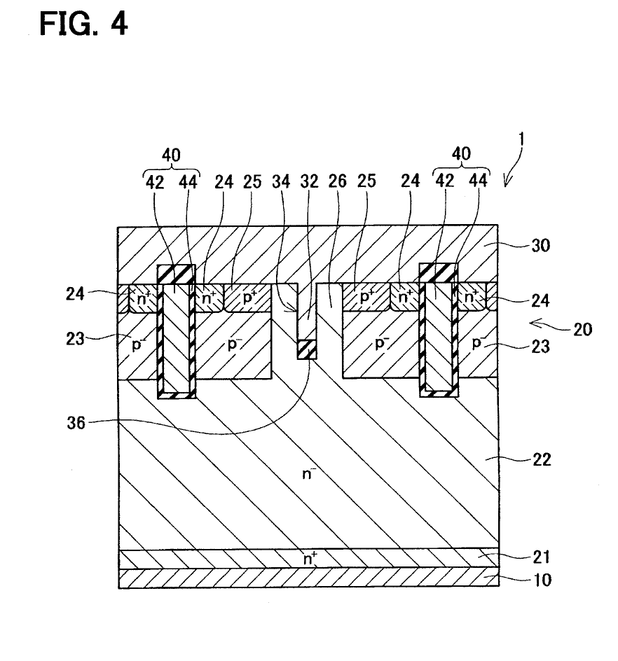

As shown in FIG. 4, an insulation region 36 may be disposed at the bottom of the trench Schottky electrode 32. The insulation region 36 contacts the bottom surface of the trench Schottky electrode 32. The insulation region 36 is filled at the bottom of the groove 34 by a chemical vapor deposition (CVD) technique, for example. In the case where the insulation region 36 is disposed at the bottom of the trench Schottky electrode 32, a breakdown due to the concentration of electric field at the bottom surface of the trench Schottky electrode 32 can be restricted.

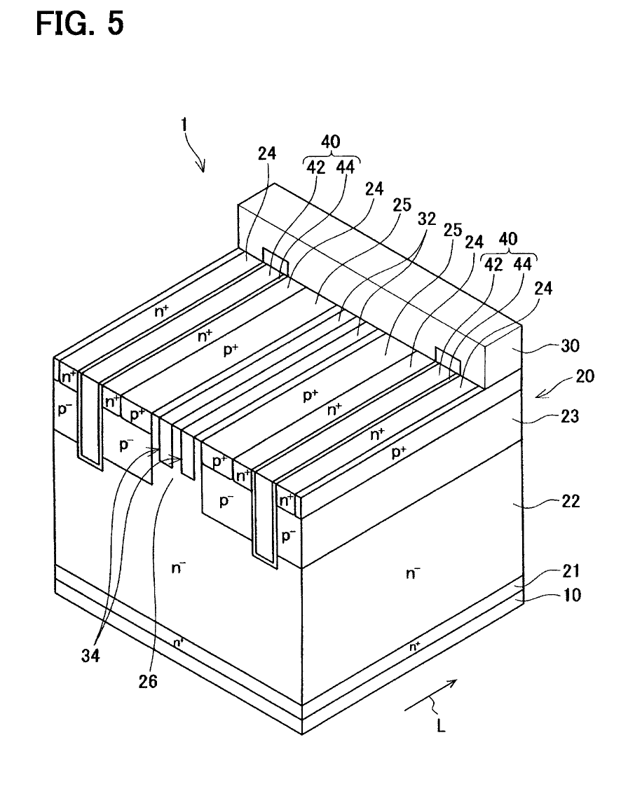

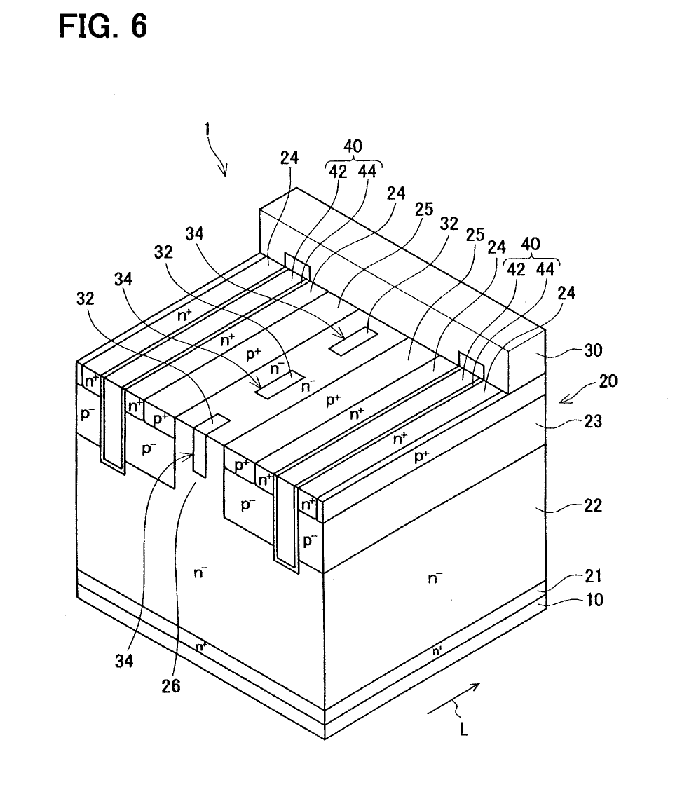

The configuration of the trench Schottky electrode 32 formed at the exposed portion of the drift region 22 is not limited to a specific one. For example, as shown in FIG. 5, a plurality of trench Schottky electrodes 32 may be disposed at the exposed portion 26 of the drift region 22. For example, as shown in FIG. 6, the trench Schottky electrode 32 may be disposed separately or discontinuously in the longitudinal direction L. Also in these cases, the effect of restricting the increase in the forward voltage of the Schottky barrier diode can be achieved.

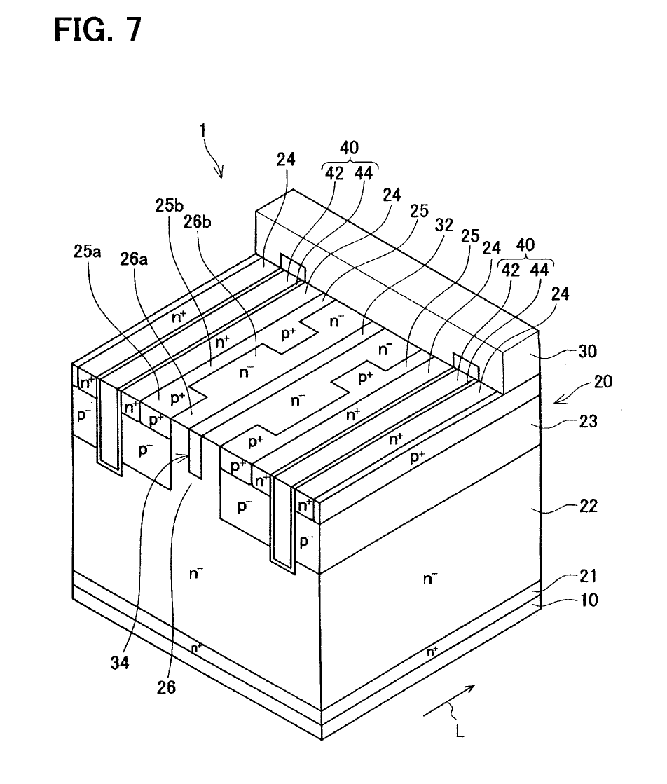

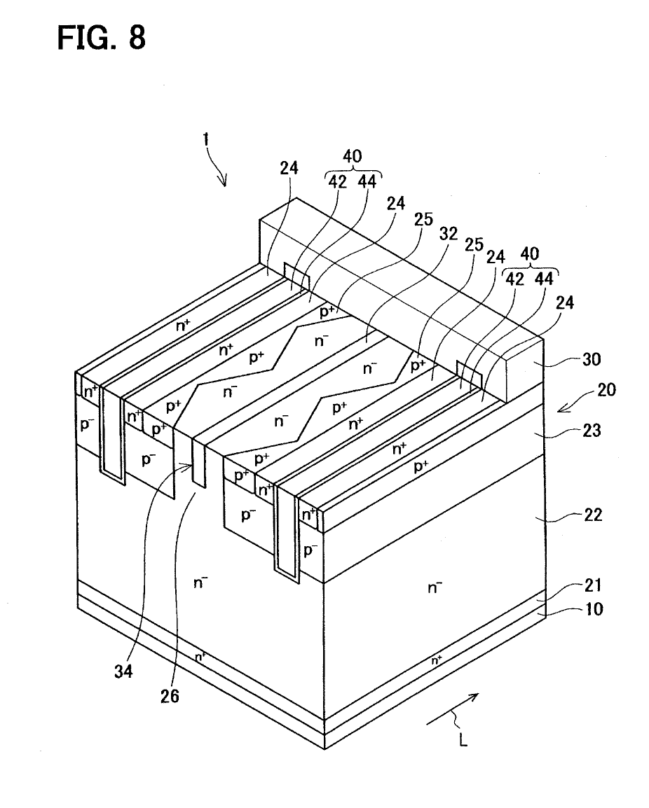

As shown in FIG. 7, the exposed portion 26 of the drift region 22 may have narrow portions 26a and wide portions 26b. The narrow portions 26a and the wide portions 26b are alternately arranged in the longitudinal direction L. In other words, the contact region 25 of the body region 23 may have wide portions 25a and narrow portions 25b alternately in the longitudinal direction L. That is, the exposed portion 26 and the contact regions 25 may be formed in such a manner that, when viewed in a direction perpendicular to the longitudinal direction L, a ratio of the width of the exposed portion 26 and the width of the contact region 25 discontinuously varies in the longitudinal direction L.

In this case, it is less likely that the latch-up will occur at the narrow portions 26a of the exposed portions 26, that is, at the wide portions 25a of the contact region 25. Therefore, the increase of the forward voltage of the Schottky barrier diode is restricted at the wide portions 26b of the exposed portion 26, that is, the narrow portions 25b of the contact region 25.

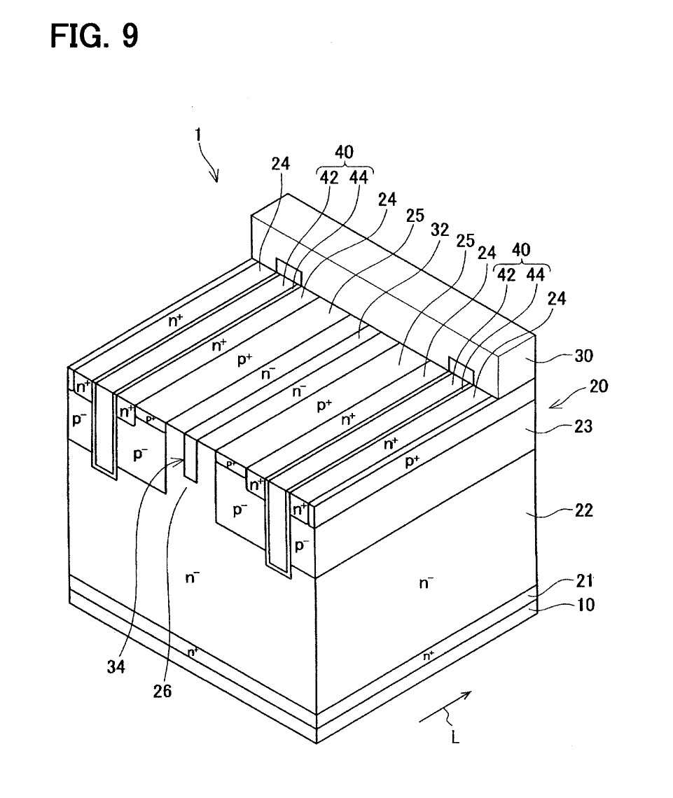

The ratio of the width of the exposed portion 26 and the width of the contact region 25 may be varied in the longitudinal direction L in any other ways. For example, a layout shown in FIG. 8 may be employed. In the example of FIG. 8, the width of the exposed portion 26 continuously or gradually varies in the longitudinal direction L. Also in this case, the occurrence of the latch-up is reduced, and the increase of the forward voltage is restricted.

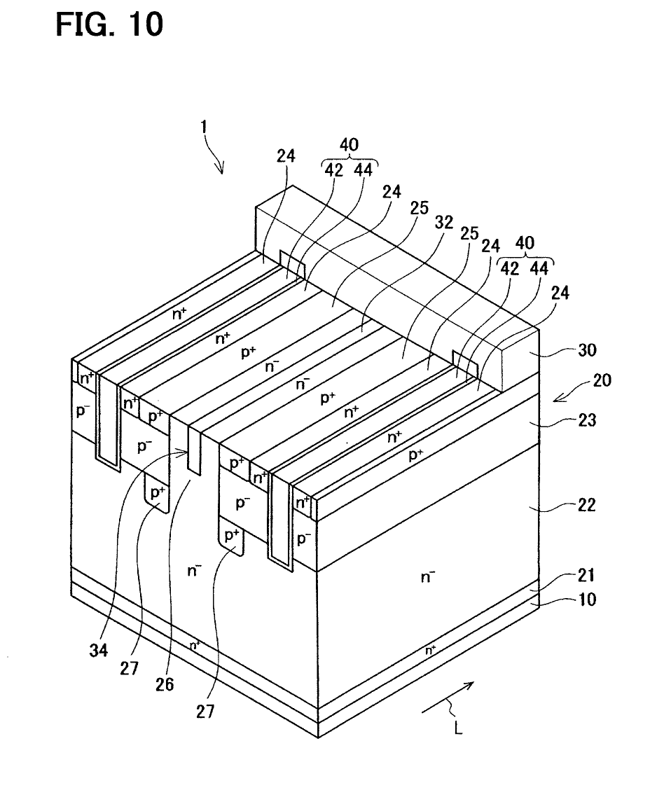

In place of or in addition to the change of the surface layout, the thickness of the contact region 25 may be changed. For example, as shown in FIG. 9, the thickness of the contact region 25 may be smaller than the source region 24. In this case, the width of the depletion layer expanding from the contact region 25 can be reduced. Therefore, the increase of the forward voltage of the Schottky barrier diode can be restricted.

As shown in FIG. 10, a p-type high impurity corner region 27 may disposed at a corner portion of the body region 23 that is adjacent to the exposed portion 26 of the drift region 22. The p-type high impurity corner region 27 has an impurity concentration higher than that of the corner of the body region 23. In the case where the high impurity corner region 27 is disposed, the electric field concentration at the corner portion of the trench gate 40 is alleviated. Thus, the breakdown due to the electric field concentration at the corner portion of the trench gate 40 can be restricted.

While only the selected exemplary embodiment and examples have been chosen to illustrate the present disclosure, it will be apparent to those skilled in the art from this disclosure that various changes and modifications can be made therein without departing from the scope of the disclosure as defined in the appended claims. Furthermore, the foregoing description of the exemplary embodiment and examples according to the present disclosure is provided for illustration only, and not for the purpose of limiting the disclosure as defined by the appended claims and their equivalents. The technical elements described hereinabove and illustrated in the drawings are useful by itself or in any combinations, and are not limited to the combinations of the appended claims described at the time of filing the application. The features exemplified hereinabove and illustrated the drawings can achieve a plurality of objectives, but can be technically useful even only by achieving one of the objectives.

What is claimed is:

1. A semiconductor device comprising:
a first conductivity-type drift region defined in a semiconductor layer, the drift region including an exposed portion exposing on a surface of the semiconductor layer;
a plurality of second conductivity-type body regions disposed on opposite sides of the exposed portion of the drift region;
a first conductivity-type source region separated from the drift region by the body region;
a gate portion opposed to the body region that separates the source region from the drift region; and
a Schottky electrode having a Schottky contact with the exposed portion of the drift region, wherein
the exposed portion of the drift region is formed with a groove, and the Schottky electrode is disposed in the groove.

2. The semiconductor device according to claim 1, wherein
the body region includes a contact region between the exposed portion and the source region,
the contact region has an impurity concentration higher than a remaining portion of the body region, and
the Schottky electrode disposed in the groove has an end at a position deeper than the contact region.

3. The semiconductor device according to claim 2, wherein
the gate portion extends in a first direction that is included in a plane of the semiconductor layer,
the exposed portion and the contact region extend in the first direction, and
a ratio of a width of the exposed portion in a second direction and a width of the contact region in the second direction varies in the first direction, the second direction being perpendicular to the first direction and being included in the plane of the semiconductor layer.

4. The semiconductor device according to claim 1, wherein
the Schottky electrode disposed in the groove has an end at a position shallower than an end of the body region.

5. The semiconductor device according to claim 1, further comprising
a second conductivity-type high impurity corner portion disposed adjacent to a corner portion of the body region, the second conductivity-type high impurity corner portion having an impurity concentration higher than that of the corner portion of the body region.

6. The semiconductor device according to claim 1, wherein
the semiconductor layer is a silicon carbide layer.

7. The semiconductor device according to claim 1, wherein
the exposed portion has a shape of projection projecting from a surface of the drift region.

8. The semiconductor device according to claim 1, wherein
the gate portion extends in a first direction that is included in a plane of the semiconductor layer,
the exposed portion extends parallel to the gate portion in the first direction, and
the Schottky electrode continuously extends in the groove of the exposed portion in the first direction.

9. The semiconductor device according to claim 1, wherein
the gate portion extends in a first direction that is included in a plane of the semiconductor layer,
the exposed portion extends parallel to the gate portion in the first direction, and
the Schottky electrode is discontinuously disposed in the first direction.

10. The semiconductor device according to claim 1, further comprising
an insulation region at a bottom of the groove and under the Schottky electrode.
